(19) United States
(12) Patent Application Publication
(10) Pub. No.: US 2024/0113158 A1
(43) Pub. Date: Apr. 4, 2024

(54) HIGH SURFACE AREA CAPACITOR IN AN ELECTRONIC SUBSTRATE PACKAGE

(71) Applicant: Intel Corporation, Santa Clara, CA (US)

(72) Inventors: Jeremy D. Ecton, Gilbert, AZ (US); Brandon C. Marin, Gilbert, AZ (US); Haobo Chen, Chandler, AZ (US); Changhua Liu, Chandler, AZ (US); Srinivas Venkata Ramanuja Pietambaram, Chandler, AZ (US)

(21) Appl. No.: 17/957,003

(22) Filed: Sep. 30, 2022

(51) Int. Cl. H01L 49/02; H01L 25/16

(52) U.S. Cl. CPC H01L 28/91; H01L 25/16; H01L 28/92

(57) ABSTRACT

Disclosed herein are microelectronics package architectures utilizing in-situ high surface area capacitor in substrate packages and methods of manufacturing the same. The substrates may include an anode material, a cathode material, and a conductive material. The anode material may have an anode surface that may define a plurality of anode peaks and anode valleys. The cathode material may have a cathode surface that may define a plurality of cathode peaks and cathode valleys complementary to the plurality of anode peaks and anode valleys. The conductive material may be located at the anode peaks.

### FIELD OF THE DISCLOSURE

The present subject matter relates to microelectronics packages. More specifically, the present disclosure relates to in-situ high surface area capacitor in substrate packages and methods of manufacturing the same.

### BACKGROUND

Passives (such as resistors, inductors, and capacitors) are devices in semiconductor packaging used for the modulation, conversion, and storage of electrical signals. Current methods of adding passives to packages center on the fabrication of discrete passive devices that are then either mounted onto the first level interconnect layer of the package or implanted into layers during build-up. As design rules continue to shrink in semiconductor packaging, so does the availability of space for discrete passives.

### BRIEF DESCRIPTION OF THE FIGURES

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1A shows a microelectronics package in accordance with at least one example of this disclosure.

FIG. 1B shows a detail of the microelectronics package in FIG. 1A in accordance with at least one example of this disclosure.

FIGS. 2A and 2B each shows subsets of peaks and valleys of a capacitor in accordance with at least one example of this disclosure.

FIG. 3 shows continuous conductive materials in accordance with at least one example of this disclosure.

FIG. 4 shows a profile in accordance with at least one example of this disclosure.

FIGS. 5A and 5B show a process for manufacturing a substrate having a capacitor in accordance with at least one example of this disclosure.

FIGS. 6A and 6B show a process for manufacturing a substrate having a capacitor in accordance with at least one example of this disclosure.

FIG. 7 shows system level diagram in accordance with at least one example of this disclosure.

### DETAILED DESCRIPTION

Disclosed herein are systems and methods of fabricating passives, such as capacitors, in parallel with build-up processes to increase the passive density, which (1) reduces electrical loss and (2) increases package functionality. Disclosed herein are inexpensive, scalable, method for fabricating a capacitor, sometimes called a spiked capacitor, which may be incorporated into a build-up of dielectric layers.

As disclosed herein, spiked capacitors may increase the effective surface area of a capacitor. The capacitor may be formed by etching through a conductive polymer matrix, which may include aluminum nanoparticles that may act as etch stops and may form rounded spikes. Aluminum may then be sputtered across the surface and oxidized to form an AlOx dielectric layer. A conductive polymer or conductive metal may then be deposited or plated onto the spiked surface forming the top electrode. Other metals and metal oxides are also possible. The capacitors disclosed herein may be fabricated in-situ with the substrate package.

The ability to pattern capacitors in-situ with the substrate may provide greater power delivery at a lower manufacturing cost. This may translate to better performance at a lower cost.

The above discussion is intended to provide an overview of subject matter of the present patent application. It is not intended to provide an exclusive or exhaustive explanation. The description below is included to provide further information.

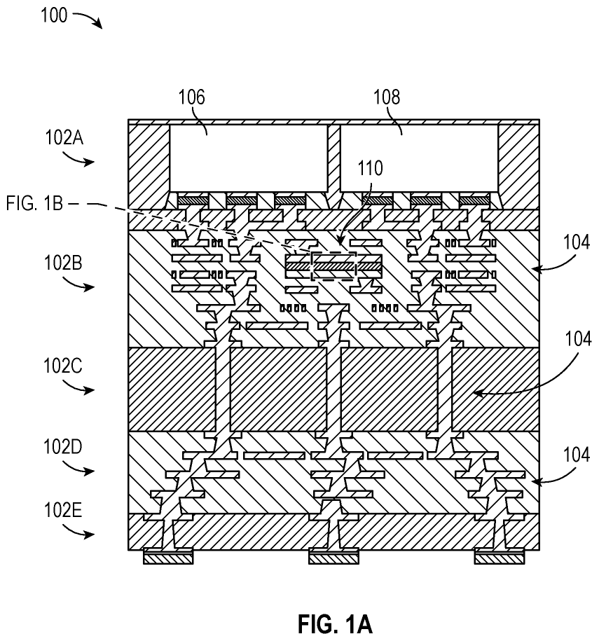

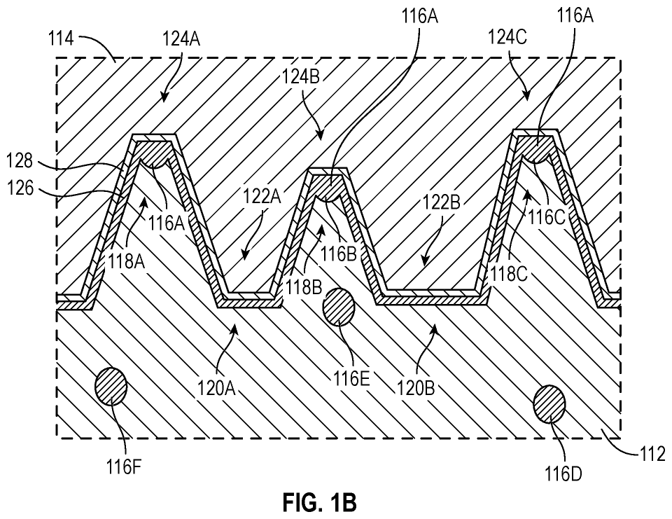

Turning now to the figures, FIG. 1A shows a microelectronics package 100 in accordance with at least one example of this disclosure. Microelectronics package 100 may include layers 102 (labeled individually as layers 102A, 102B, 102C, 102D, and 102E). Layers 102 may include traces and via 104, as well as dies 106 and 108, and a substrate package 110.

FIG. 1B shows a detail of substrate package 110 in accordance with at least one example of this disclosure. Substrate package 110 may include an anode material 112 and a cathode material 114. Anode material 112 may be a conductive polymer. Anode material 112 may include a plurality of nanoparticles 116 (labeled individually as nanoparticles 116A, 116B, 116C, 116D, 116E, and 116F). Nanoparticles 116 may be conductive particles dispersed throughout anode material 112. During fabrication of substrate package 110, nanoparticles 116 may act as a mask during an etching process such that particles close to a surface 111, such as nanoparticles 116A, 116B, and 116C may inhibit etching and allow the etching process to form peaks 118 (labeled individually as peaks 118A, 118B, and 118C) and valleys 120 (labeled individually as valleys 120A and 120B). Nanoparticles 116 may be a conductive material located at peaks 118.

Cathode material 114 may be etched to form peaks 122 (labeled individually as peaks 122A and 122B) and valleys 124 (labeled individually as valleys 124A, 124B, and 124C). Peaks 118 and valleys 120 can be complementary to peaks 122 and valleys 124 such that peaks 118 and valleys 120 mesh with peaks 122 and valleys 124 to form a capacitor as disclosed herein.

Substrate package 110 may also include a metallic layer 126. As disclosed herein, metallic layer 126 may be a solid metallic layer that is deposited onto the spiked architecture of anode material 112. Once deposited, an oxide layer 128 may be formed. Metallic layer 126 and oxide layer 128 may form a dielectric. Metallic layer 128 may be a metallic material such as, but not limited to, copper, aluminum, or a combination thereof. For example, metallic layer 126 may be an aluminum material and oxide layer 128 may be an aluminum oxide compound that together form a dielectric portion of a capacitor that is located in between anode material 112 and cathode material 114.

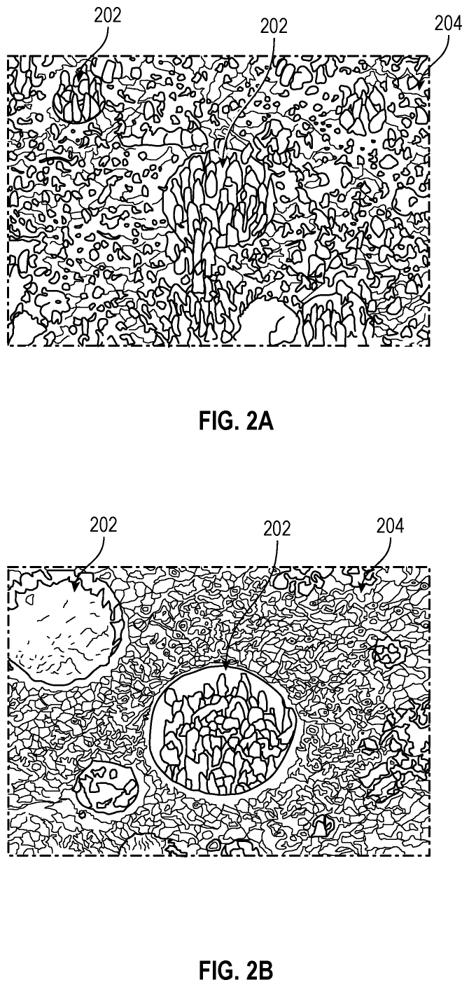

While FIGS. 1A and 1B show a set of peaks and valleys, substrate package 110 may define subsets of peeks and valleys that are distributed across surface 111. FIGS. 2A and 2B each shown examples of subsets of peeks and valleys 202 distributed across a surface 204. Peaks and valleys 202 shown in FIGS. 2A and 2B were formed using a dry etching process.

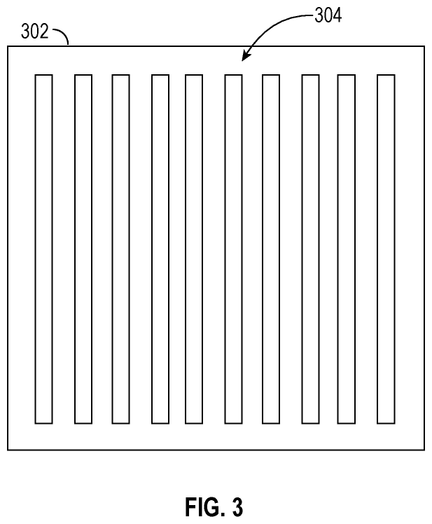

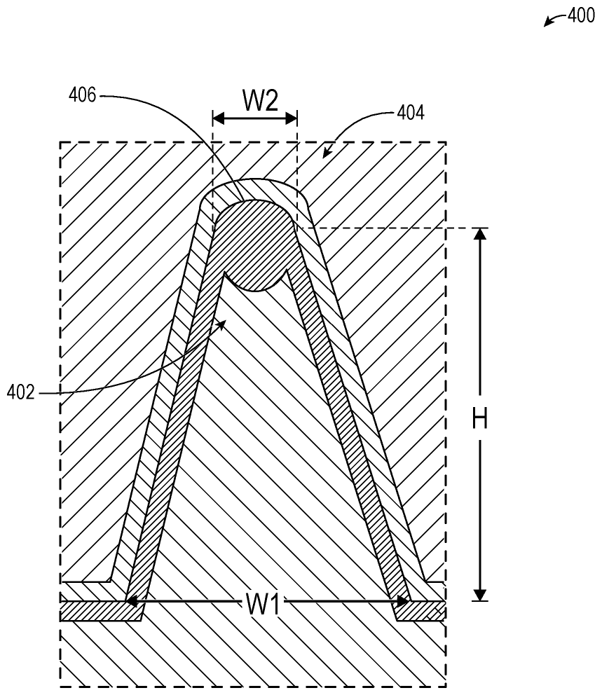

Still consistent with embodiments disclosed herein, the peaks of the capacitor may be formed by a continuous conduct material. FIG. 3 shows an anode material 300 that includes strips 304. Strips 304 may also be shorter segment that form squares or dots. Each of strips 304 may be a conductive material. During an etching process as disclosed herein, each of strips 304 may act as a mask to hinder etching of anode material 302, thus forming continuous peaks and valleys as disclosed herein. Each of strips 304 may be connected to one other and/or one or more subsets of strips 304 may be connected together to form subsets of continuous portions of conductive materials.

FIG. 4 shows a profile for a spiked portion 400 of a capacitor in accordance with at least one example of this disclosure. Spiked portion 400 may be representative of a peak and valley of any combination of anode and cathode materials disclosed herein. As shown in FIG. 4, a peak 402, and corresponding valley 404, may have a height, H, which may range from about 2 μm to about 100 μm. The base of peek 402, or opening for valley 404, may have a width, W1, which may range from about 2 μm to about 10 μm. A width, W2, of a valley 404, or point of peak 402, may range from about 1 μm to about 2 μm. As shown in FIG. 4, peak 402 may have a rounded profile 406.

Table 1 shows capacitance values for various geometries. For the values in Table 1, it was assumed that a nanoparticle has a diameter of ˜1 μm and the etching profile around the nanoparticle is conical in shape with a base diameter of ˜2 μm. Heights ranging from 0 μm (standard thin film capacitor, non-spiked), 2 μm, 5 μm, 10 μm, and up to 100 μm were assumed for the calculations. Also, an oxide thickness of ˜5 nm was assumed. As shown in Table 1, capacitance values as high as 138 uF/cm2 may be possible using the systems and methods disclosed herein.

TABLE 1
Capacitance Values for Various Spike Geometries

| | | | | | | SA Scale | |
|---|---|---|---|---|---|---|---|
| Dielectric | Dielectric | | | | SA | Factor SA | Capacitance |
| Constant | Thickness | W2 | W1 | | (cone) | vs. SA at | (effective) |
| (AlOx | (μm) | (μm) | (μm) | H (μm) | (μm²) | H = 0 μm | μF/cm² |
| 7.8 | .005 | 1 | 2 | 0 | 3.14 | 1 | 1.38 |
| 7.8 | .005 | 1 | 2 | 2 | 7 | 2x | 2.76 |
| 7.8 | .005 | 1 | 2 | 5 | 16 | 5x | 6.9 |
| 7.8 | .005 | 1 | 2 | 10 | 31 | 10x | 13.8 |
| 7.8 | .005 | 1 | 2 | 100 | 314 | 100x | 138 |

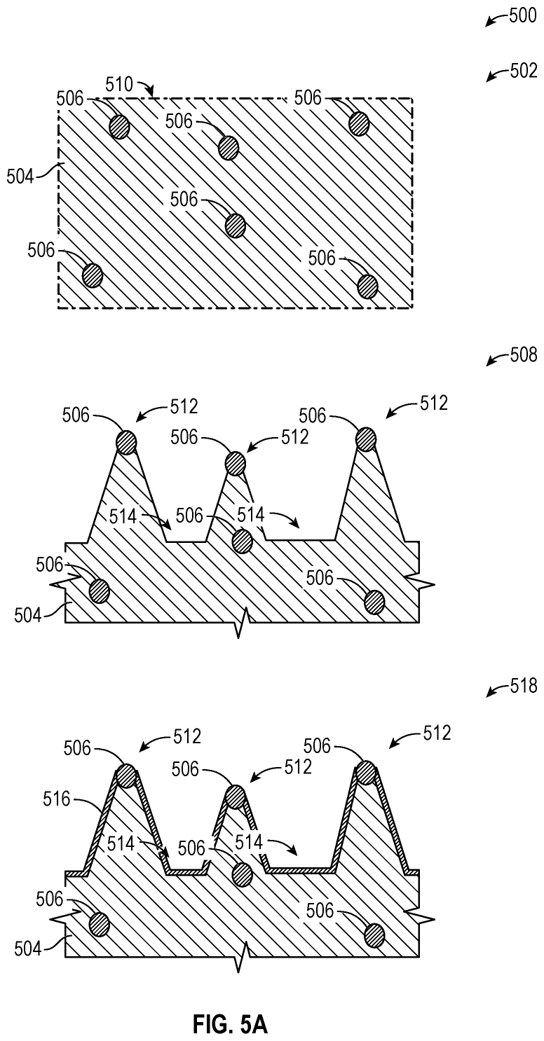

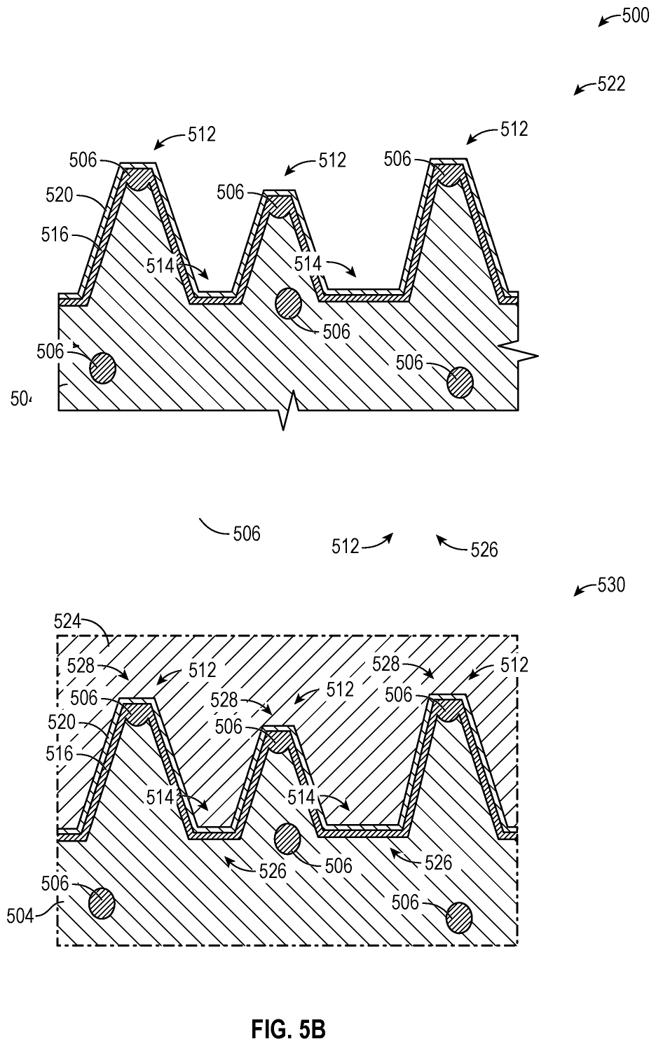

FIGS. 5A and 5B show a process flow 500 for manufacturing a substrate having a capacitor in accordance with at least one example of this disclosure. Process flow 500 may begin at stage 502, where a conductive polymer 504 may be impregnated with nanoparticles 506. From stage 502, process flow 500 may proceed to stage 508 where a surface 510 of conductive polymer 504, e.g., an anode material, may be etched to form peaks 512 and valleys 514. Etching surface 510 may include the use of a dry or wet etching process. Also, conductive polymer 504 may be lithographically patterned to form a capacitor in-situ, however, other methods can be used to pattern the capacitor (i.e., peaks 512 and valleys 514) including laser ablation or dry etching through a mask. Thus, etching surface 510 may include creating a mask on surface 510 prior to etching surface 510.

Once peaks 512 and valleys 514 are formed, a conductive material 516 may be deposited onto surface 510 formed by the etching process (518). Conductive material 516 may be the same material that us used to form nanoparticles 506. For example, conductive material 516 and nanoparticles 506 may both be made of aluminum, copper, or any combination thereof. Depositing conductive material 516 onto surface 510 may include depositing conductive material 516 in a continuous pattern onto surface 510. For example, as shown in FIGS. 5A and 5B, conductive material 516 may be a continuous layer of material. Depositing conductive material 516 may include depositing conductive material 516 via a sputtering process. For instance, conductive material 516 may be aluminum that is deposited via an aluminum sputter deposition process.

Once conductive material 516 is deposited, a dielectric layer 520 may be formed on conductive material 516 (522). Forming dielectric layer 520 may include allowing conductive material 516 to for oxides. For example, forming dielectric layer 520 may include allowing an oxide layer to form on conductive material 516.

After dielectric layer 520 is formed, a cathode 524 having peaks 526 and valleys 528 complementary to peaks 512 and valleys 514 may be formed (530). For example, forming cathode 524 may include depositing a copper, tin, silver, gold materials or any alloys thereof onto dielectric layer 520.

FIGS. 2A and 2B show an example of forming rounded spikes for peaks and valleys. The rounded spikes were formed by etching silicon fillers in solder resist, which had magnesium and aluminum impurities in the filler (FIG. 3B). Other mechanisms may be used for creating rounded spikes in solder resist. For example, energy-dispersive X-ray (EDX) shows that a silica filler contained Mg and Al may not be etched by the dry etch gas consisting of Flourine and the impurities may act as etch stops.

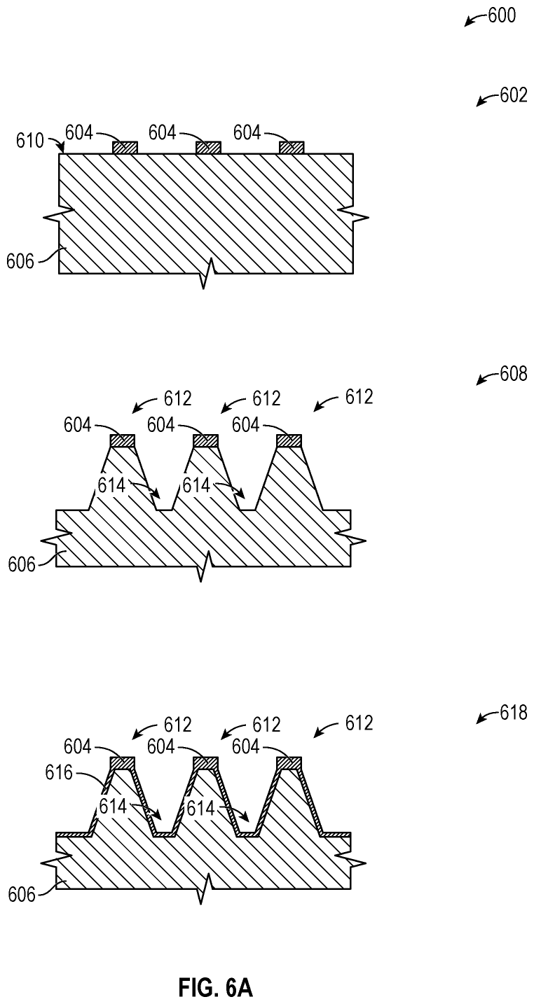

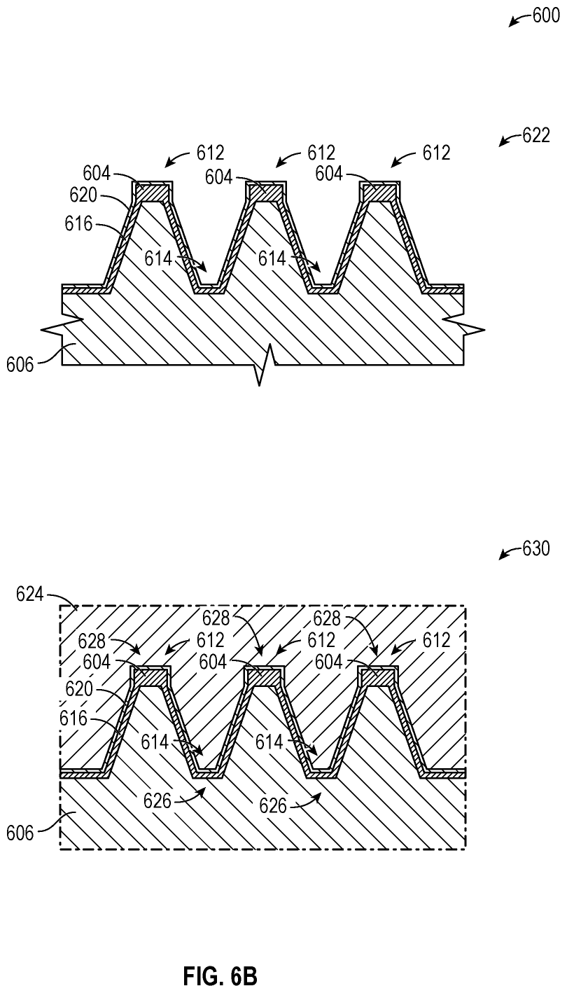

FIGS. 6A and 6B show a process flow 600 for manufacturing a substrate having a capacitor in accordance with at least one example of this disclosure. Process flow 600 may begin at stage 602, where a hard mask 604 may be deposited onto a conductive polymer 606. Hard mask 604 may be strips of metal or other masking material that are deposited onto a surface 608 of conductive polymer 606. Hard mask 604 may be a well-defined hard mask as outlined in FIG. 3. Use of hard mask 604 may enable predictable capacitance relative to randomly placed nanoparticles. Examples of a mask material may include, but are not limited to, aluminum, magnesium, iron, etc.

From stage 602, process flow 600 may proceed to stage 608 where a surface 610 of conductive polymer 602, e.g., an anode material, may be etched to form peaks 612 and valleys 614. Etching surface 610 may include the use of a dry or wet etching process, laser ablation etc.

Once peaks 612 and valleys 614 are formed, a conductive material 616 may be deposited onto surface 610 formed by the etching process (618). Conductive material 616 may be the same material that us used to form hard mask 604. For example, conductive material 616 may be made of aluminum, copper, or any combination thereof. Depositing conductive material 616 onto surface 610 may include depositing conductive material 616 in a continuous pattern onto surface 610. For example, as shown in FIGS. 6A and 6B, conductive material 616 may be a continuous layer of material. Depositing conductive material 616 may include depositing conductive material 616 via a sputtering process. For instance, conductive material 616 may be aluminum that is deposited via an aluminum sputter deposition process.

Once conductive material 616 is deposited, a dielectric layer 620 may be formed on conductive material 516 (622). Forming dielectric layer 620 may include allowing conductive material 616 to for oxides. For example, forming dielectric layer 620 may include allowing an oxide layer to form on conductive material 616.

After dielectric layer 620 is formed, a cathode 624 having peaks 626 and valleys 628 complementary to peaks 612 and valleys 614 may be formed (630). For example, forming cathode 624 may include depositing a copper material onto dielectric layer 620.

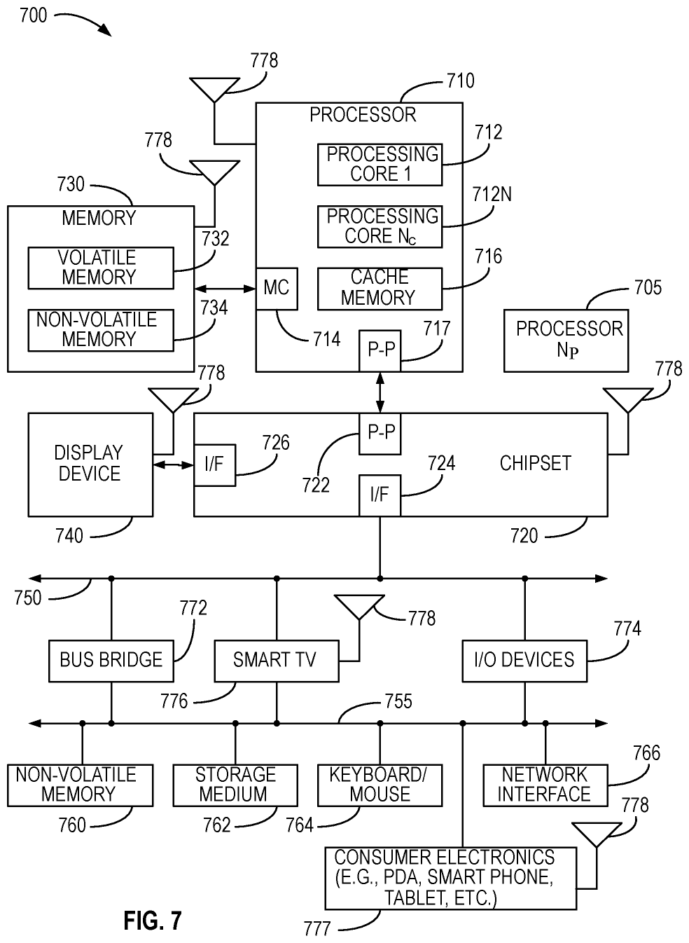

FIG. 7 illustrates a system level diagram, according to one embodiment of the invention. For instance, FIG. 7 depicts an example of an electronic device (e.g., system) including microelectronics package 100 as described herein. FIG. 7 is included to show an example of a higher-level device application for the present invention. In one embodiment, system 700 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 700 is a system on a chip (SOC) system.

In one embodiment, processor 710 has one or more processing cores 712 and 712N, where 712N represents the Nth processor core inside processor 710 where N is a positive integer. In one embodiment, system 700 includes multiple processors including 710 and 705, where processor 705 has logic similar or identical to the logic of processor 710. In some embodiments, processing core 712 includes, but is not limited to, pre-fetch logic to fetch instructions, decode logic to decode the instructions, execution logic to execute instructions and the like. In some embodiments, processor 710 has a cache memory 716 to cache instructions and/or data for system 700. Cache memory 716 may be organized into a hierarchal structure including one or more levels of cache memory.

In some embodiments, processor 710 includes a memory controller 714, which is operable to perform functions that enable the processor 710 to access and communicate with memory 730 that includes a volatile memory 732 and/or a non-volatile memory 734. In some embodiments, processor 710 is coupled with memory 730 and chipset 720. Processor 710 may also be coupled to a wireless antenna 778 to communicate with any device configured to transmit and/or receive wireless signals. In one embodiment, the wireless antenna interface 778 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 732 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory 730 stores information and instructions to be executed by processor 710. In one embodiment, memory 730 may also store temporary variables or other intermediate information while processor 710 is executing instructions. In the illustrated embodiment, chipset 720 connects with processor 710 via Point-to-Point (PtP or P-P) interfaces 717 and 722. Chipset 720 enables processor 710 to connect to other elements in system 700. In some embodiments of the invention, interfaces 717 and 722 operate in accordance with a PtP communication protocol such as the Intel® QuickPath Interconnect (QPI) or the like. In other embodiments, a different interconnect may be used.

In some embodiments, chipset 720 is operable to communicate with processor 710, 705N, display device 740, and other devices 772, 776, 774, 760, 762, 764, 766, 777, etc. Chipset 720 may also be coupled to a wireless antenna 778 to communicate with any device configured to transmit and/or receive wireless signals.

Chipset 720 connects to display device 740 via interface 726. Display 740 may be, for example, a liquid crystal display (LCD), a plasma display, cathode ray tube (CRT) display, or any other form of visual display device. In some embodiments of the invention, processor 710 and chipset 720 are merged into a single SOC. In addition, chipset 720 connects to one or more buses 750 and 755 that interconnect various elements 774, 760, 762, 764, and 766. Buses 750 and 755 may be interconnected together via a bus bridge 772. In one embodiment, chipset 720 couples with a non-volatile memory 760, a mass storage device(s) 762, a keyboard/mouse 764, and a network interface 766 via interface 724 and/or 704, smart TV 776, consumer electronics 777, etc.

In one embodiment, mass storage device 762 includes, but is not limited to, a solid state drive, a hard disk drive, a universal serial bus flash memory drive, or any other form of computer data storage medium. In one embodiment, network interface 766 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) can be incorporated into processor core 712.

### Additional Notes

The following, non-limiting examples, detail certain aspects of the present subject matter to solve the challenges and provide the benefits discussed herein, among others.

Example 1 is a microelectronics package comprising: a first electrode material having a first electrode surface, the first electrode surface defining a plurality of first electrode peaks and first electrode valleys; a second electrode material having a second electrode surface, the second electrode surface defining a plurality of second electrode peaks and second electrode valleys complementary to the plurality of first electrode peaks and first electrode valleys; and a conductive material located at the first electrode peaks; and a die attached to the second electrode material.

In Example 2, the subject matter of Example 1 optionally includes wherein the first electrode material is an anode material and the second electrode material is a cathode material.

In Example 3, the subject matter of any one or more of Examples 1-2 optionally include a dielectric material located in between the anode material and the cathode material.

In Example 4, the subject matter of any one or more of Examples 1-3 optionally include conductive particles dispersed throughout the first electrode material.

In Example 5, the subject matter of any one or more of Examples 1-4 optionally include wherein the first electrode material is a conductive polymer material.

In Example 6, the subject matter of any one or more of Examples 1-5 optionally include wherein the conductive material comprises a continuous conductive material.

In Example 7, the subject matter of any one or more of Examples 1-6 optionally include wherein the conductive material comprises nanoparticles.

In Example 8, the subject matter of any one or more of Examples 1-7 optionally include wherein the conductive material is a solid layer of a metallic material.

In Example 9, the subject matter of any one or more of Examples 7-8 optionally include wherein the metallic material is copper, aluminum, or a combination thereof.

In Example 10, the subject matter of any one or more of Examples 1-9 optionally include wherein the first electrode peaks have a height of about 2 μm to about 100 μm.

In Example 11, the subject matter of any one or more of Examples 1-10 optionally include wherein the first electrode peaks have a rounded profile.

Example 12 is a microelectronics package, the substrate comprising: a plurality of dies; a first electrode material having an first electrode surface, the first electrode surface defining: a first subset of first electrode peaks and first electrode valleys, and a second subset of first electrode peaks and first electrode valleys; a second electrode material connected to the plurality of dies and having a second electrode surface, the second electrode surface defining: a first subset of second electrode peaks and second electrode valleys complementary to the first subset of first electrode peaks and first electrode valleys, and a second subset of second electrode peaks and second electrode valleys complementary to the second subset of first electrode peaks and first electrode valleys; and a conductive material located at the first and second subsets of first electrode peaks.

In Example 13, the subject matter of any one or more of Examples 1-12 optionally include wherein the first electrode material is an anode material and the second electrode material is a cathode material.

In Example 14, the subject matter of any one or more of Examples 11-13 optionally include a dielectric material located in between the first electrode material and the second electrode material.

In Example 15, the subject matter of any one or more of Examples 11-14 optionally include conductive particles dispersed throughout the first electrode material.

In Example 16, the subject matter of any one or more of Examples 11-15 optionally include wherein the first electrode material is a conductive polymer material.

In Example 17, the subject matter of any one or more of Examples 11-16 optionally include wherein the conductive material comprises a continuous conductive material.

In Example 18, the subject matter of any one or more of Examples 11-17 optionally include wherein the conductive material comprises nanoparticles.

In Example 19, the subject matter of any one or more of Examples 11-18 optionally include wherein the conductive material is a solid layer of a metallic material.

In Example 20, the subject matter of any one or more of Examples 17-19 optionally include wherein the metallic material is copper, aluminum, or a combination thereof.

In Example 21, the subject matter of any one or more of Examples 11-20 optionally include wherein the first and second subsets of first electrode peaks have a height of about 2 μm to about 100 μm.

In Example 22, the subject matter of any one or more of Examples 11-21 optionally include wherein the first and second subsets of first electrode peaks have a rounded profile.

Example 23 is a method of manufacturing a substrate for a microelectronics package, the method comprising: forming a plurality of first electrode peaks and first electrode valleys in a first electrode material; depositing a conductive material onto the first electrode peaks and first electrode valleys; forming a dielectric layer on the conductive material; forming a plurality of second electrode peaks and second electrode valleys complementary to the first electrode peaks and first electrode valleys in a second electrode material; and attaching a die to the second electrode material.

In Example 24, the subject matter of any one or more of Examples 19-23 optionally include wherein forming the plurality of first electrode peaks and first electrode valleys in the first electrode material comprises forming the plurality of first electrode peaks and first electrode valleys in an anode material; and forming the plurality of second electrode peaks and second electrode valleys in the second electrode material comprises forming the plurality of second electrode peaks and second electrode valleys in a cathode material.

In Example 25, the subject matter of any one or more of Examples 23-24 optionally include wherein depositing the conductive material onto the anode surface comprises depositing the conductive material in a continuous pattern onto the anode surface.

In Example 26, the subject matter of any one or more of Examples 23-25 optionally include wherein depositing the conductive material comprises depositing aluminum via an aluminum sputter deposition process.

In Example 27, the subject matter of any one or more of Examples 23-26 optionally include wherein etching the anode surface comprises dry etching the anode surface.

In Example 28, the subject matter of any one or more of Examples 23-27 optionally include creating a mask on the anode surface prior to etching the anode surface.

In Example 29, the subject matter of any one or more of Examples 23-28 optionally include wherein forming the dielectric layer comprising forming an oxide layer on the conductive material.

In Example 30, the subject matter of any one or more of Examples 23-29 optionally include wherein forming the cathode comprises depositing a copper material on the dielectric layer.

In Example 31, the microelectronics packages, systems, apparatuses, or method of any one or any combination of Examples 1-30 can optionally be configured such that all elements or options recited are available to use or select from.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A microelectronics package comprising:
a first electrode material having a first electrode surface, the first electrode surface defining a plurality of first electrode peaks and first electrode valleys;
a second electrode material having a second electrode surface, the second electrode surface defining a plurality of second electrode peaks and second electrode valleys complementary to the plurality of first electrode peaks and first electrode valleys; and
a conductive material located at the first electrode peaks; and
a die attached to the second electrode material.

2. The microelectronics package of claim 1, wherein the first electrode material is an anode material and the second electrode material is a cathode material.

3. The A microelectronics package of claim 1, further comprising a dielectric material located in between the anode material and the cathode material.

4. The A microelectronics package of claim 1, further comprising conductive particles dispersed throughout the first electrode material.

5. The A microelectronics package of claim 1, wherein the first electrode material is a conductive polymer material.

6. The A microelectronics package of claim 1, wherein the conductive material comprises a continuous conductive material.

7. The A microelectronics package of claim 1, wherein the conductive material comprises nanoparticles.

8. The A microelectronics package of claim 1, wherein the conductive material is a solid layer of a metallic material.

9. The A microelectronics package of claim 7, wherein the metallic material is copper, aluminum, or a combination thereof.

10. The A microelectronics package of claim 1, wherein the first electrode peaks have a height of about 2 μm to about 100 μm.

11. The A microelectronics package of claim 1, wherein the first electrode peaks have a rounded profile.

12. A microelectronics package, the substrate comprising:
a plurality of dies;
a first electrode material having an first electrode surface, the first electrode surface defining:
a first subset of first electrode peaks and first electrode valleys, and
a second subset of first electrode peaks and first electrode valleys;
a second electrode material connected to the plurality of dies and having a second electrode surface, the second electrode surface defining:
a first subset of second electrode peaks and second electrode valleys complementary to the first subset of first electrode peaks and first electrode valleys, and
a second subset of second electrode peaks and second electrode valleys complementary to the second subset of first electrode peaks and first electrode valleys; and
a conductive material located at the first and second subsets of first electrode peaks.

13. The microelectronics package of claim 1, wherein the first electrode material is an anode material and the second electrode material is a cathode material.

14. The microelectronics package of claim 11, further comprising a dielectric material located in between the first electrode material and the second electrode material.

15. The microelectronics package of claim 11, further comprising conductive particles dispersed throughout the first electrode material.

16. The microelectronics package of claim 11, wherein the first electrode material is a conductive polymer material.

17. The microelectronics package of claim 11, wherein the conductive material comprises nanoparticles.

18. The microelectronics package of claim 11, wherein the conductive material is a solid layer of a metallic material.

19. A method of manufacturing a substrate for a microelectronics package, the method comprising:
forming a plurality of first electrode peaks and first electrode valleys in a first electrode material;
depositing a conductive material onto the first electrode peaks and first electrode valleys;
forming a dielectric layer on the conductive material;
forming a plurality of second electrode peaks and second electrode valleys complementary to the first electrode peaks and first electrode valleys in a second electrode material; and
attaching a die to the second electrode material.

20. The method of claim 19, wherein
forming the plurality of first electrode peaks and first electrode valleys in the first electrode material comprises forming the plurality of first electrode peaks and first electrode valleys in an anode material; and
forming the plurality of second electrode peaks and second electrode valleys in the second electrode material comprises forming the plurality of second electrode peaks and second electrode valleys in a cathode material.

21. The method of claim 19, wherein depositing the conductive material onto the anode surface comprises depositing the conductive material in a continuous pattern onto the anode surface.

22. The method of claim 19, wherein depositing the conductive material comprises depositing aluminum via an aluminum sputter deposition process.

23. The method of claim 19, wherein etching the anode surface comprises dry etching the anode surface.

24. The method of claim 19, further comprising creating a mask on the anode surface prior to etching the anode surface.

25. The method of claim 19, wherein forming the dielectric layer comprising forming an oxide layer on the conductive material.
